(19) United States
(12) Patent Application Publication
(10) Pub. No.: US 2006/0267024 A1
(43) Pub. Date: Nov. 30, 2006

(54) Semiconductor layer structure and process for producing a semiconductor layer structure

(75) Inventors: Brian Murphy, Pfarrkirchen (DE); Maik Haeberlen, Augsburg (DE); Joerg Lindner, Bobingen (DE)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 11/438,511

(22) Filed: May 22, 2006

(30) Foreign Application Priority Data
May 25, 2005 (DE) 10 2005 024 073.9

(51) Int. Cl. H01L 31/0312

(52) U.S. Cl. 257/77

(57) ABSTRACT

The invention relates to a semiconductor layer structure of a monocrystalline silicon carbide layer on a ≧150 mm diameter silicon wafer, the silicon carbide layer having a surface roughness of at most 0.5 nm RMS and a micropipe density of at most 1 cm⁻² and being free of defects produced during crystal growth or epitaxial deposition, and to a process for producing such a semiconductor layer structure, by implanting carbon ions into a silicon wafer, heat treating the silicon wafer to produce a buried monocrystalline silicon carbide layer and flanking noncrystalline transition regions, followed by removing the upper silicon layer and noncrystalline transition region above the monocrystalline silicon carbide layer, thus uncovering the monocrystalline silicon carbide layer, and chemical mechanical planarizing the monocrystalline silicon carbide layer to a surface roughness of less than 0.5 nm RMS.

### BACKGROUND OF THE INVENTION

1. Field of the Invention

The invention relates to a semiconductor layer structure which comprises a monocrystalline silicon carbide layer on a silicon substrate and is suitable as substrate for epitaxial growth of semiconductor materials. The invention also relates to a process for producing a semiconductor layer structure.

2. Background Art

On account of its materials properties, for example a high Schottky barrier, high breakdown field strength, and high thermal conductivity, silicon carbide is the ideal material for power components with a high blocking capability. Silicon carbide allows the production of smaller, more lightweight components with short switching times, and which do not require complex cooling, since the components are not greatly heated even under high stresses. Silicon carbide is also suitable for the production of optoelectronic components, since its lattice constant is closer than the lattice constants of silicon or sapphire to the lattice constants of typical semiconductor materials used for optoelectronics, such as for example nitride compound semiconductors. This has an advantageous effect on the avoidance of defects during the epitaxial growth of nitride compound semiconductors on silicon carbide.

On account of the difficult production process, silicon carbide obtained by the growth of single crystals is relatively expensive, and the silicon carbide wafers obtained are only available up to a diameter of 100 mm. Moreover, what are known as micropipe defects occur along the <0001> c axis during the conventionally used PVT (physical vapor transport) growth of silicon carbide single crystals (N. Ohtani in “Silicon carbide: recent major advances”/W. J. Choyke, H. Matsunami, G. Pensl (eds.), pp. 138 ff, Springer-Verlag Berlin Heidelberg 2004, ISBN 3-540-40458-9). These micropipe defects are passages or pipes with diameters of from a few hundred nm to several μm, which propagate along the c axis through the silicon carbide single crystal. Micropipes occur in PVT-grown silicon carbide single crystals with a density of up to 100 cm⁻². Attempts have been made to fill the micropipe passages for example by deposition of an up to 100 μm thick epitaxial silicon carbide layer. However, in this way it has only been possible to reduce the micropipe density to 10 cm⁻², which is still unsatisfactory since the occurrence of micropipe defects in the device-active region leads to destruction of the component.

Heteroepitaxial growth of silicon carbide on silicon substrates likewise leads to problems, in particular on account of the high dislocation density, which is attributable to the lattice misfit with silicon. During growth of gallium nitride on heteroepitaxial silicon carbide layers, a misfit dislocation density of at least 10¹⁰ cm⁻² usually ensues.

As an alternative, it has been proposed that an ion beam synthesis (IBS) be used in order to produce a buried silicon carbide layer in a silicon substrate. In this process, carbon ions are implanted at a high velocity into a monocrystalline silicon substrate and this substrate is then subjected to a high-temperature treatment in order to produce a buried silicon carbide layer. The dose of ion beams, the energy required, the implantation temperature of the substrate and the high-temperature treatment conditions determine the crystallinity of the implanted region beneath the surface of the silicon substrate. A monocrystalline layer of 3C silicon carbide (3C: Ramsdell notation for cubic crystal structure with a periodicity over 3 bilayers) can be produced several hundred nanometers beneath the surface of the substrate by altering the dose, the required energy, the implantation temperature and the high-temperature treatment conditions. The polycrystalline region above the crystalline silicon carbide layer contains a multiplicity of defects and silicon carbide precipitates. The buried silicon carbide layer can be uncovered by removing the silicon layer above. The uncovered surface consists of monocrystalline 3C silicon carbide and could in principle be used as a substrate for epitaxial growth. However, it has been found that the roughness of the silicon carbide surface obtained is too high to allow epitaxial semiconductor layers of a high quality to be deposited on a substrate of this type.

By way of example, it has been proposed that the uppermost silicon layer be removed by etching with tetramethylammonium hydroxide (TMAH) (Romano-Rodriguez et al., Materials Science Forum, Vols. 338-342 (2000), pp. 309-312). The uncovered silicon carbide surface was then used as substrate for epitaxial growth of silicon carbide at 1350° C. using silane and propane as source gases and hydrogen as carrier gas. The resulting epitaxial layer had a high density of stacking faults. This is because TMAH has a very low etching action on silicon carbide (Zetterling et al., Process technology for silicon carbide Devices, Chapter 4, ISBN 0 85296 998 8). Therefore, it is not possible to remove silicon carbide nanocrystallites above the buried silicon carbide layer by etching using TMAH. The uncovered silicon carbide surface is rough, includes silicon carbide nanocrystallites and is therefore unsuitable as a substrate for epitaxial growth.

The etching of the silicon carbide surface with HF/HNO₃ (hydrofluoric acid/nitric acid) likewise led to a rough surface which was unsuitable for high-quality epitaxial growth. This is likewise attributable to the difficulties of etching silicon carbide nanocrystallites at the silicon carbide surface.

It is proposed in WO03/034484 that first of all a part of the uppermost silicon layer, which is joined to the buried 3C silicon carbide layer, be rendered amorphous. This involves the implantation of, for example, helium ions. Then, the buried 3C silicon carbide layer is uncovered by etching using HF/HNO₃ (hydrofluoric acid/nitric acid). The resulting surface is considerably improved as a result, and a roughness of 0.7 nm RMS (root mean square) is achieved. However, even this roughness value is too high for high-quality epitaxial growth.

The roughness of a silicon carbide surface that is suitable for epitaxial deposition should be at most 0.5 nm RMS. It has therefore been attempted to smooth the silicon carbide surface by mechanical polishing, for example using diamond abrasive, by chemical processing steps, such as etching using acidic or alkaline media, and by chemical mechanical processing steps, i.e. by partial chemical reaction and partial mechanical removal of material (abrasion).

By way of example, it has been proposed that the uppermost silicon layer, which is joined to the buried silicon carbide layer, be removed by means of thermal oxidation at 1050° C. for a period of 40 min and subsequent elimination of the oxide which forms by etching using an HF/HNO₃ solution (Journal of Crystal Growth, vol. 261, 266 (2004)). Then, a 3-4 μm thick gallium nitride layer was grown epitaxially on the uncovered silicon carbide surface. It has been found that although the gallium nitride surface obtained did not have any cracks or fractures, it was relatively rough and unsuitable for the structuring of components.

The attempt to smooth the rough silicon carbide surface by diamond polishing and thereby to prepare it for the epitaxial deposition of semiconductor material leads to scratches with a depth of up to 5 nm on the surface.

Furthermore, it has been attempted to use CMP (chemical mechanical polishing) to planarize a silicon carbide surface which has undergone preliminary mechanical polishing by means of diamond slurry (J. Electrochem. Soc., Vol. 144, No. 6, June 1997). At CMP slurry pHs above 10, a temperature of more than 55° C., a polishing time of approximately 30 minutes and material removal rates of 0.2 μm/h, relatively good results have been achieved. A high level of material removal of approximately 100 nm was required in order to remove the deep scratches on the silicon carbide surface caused by the preliminary mechanical polishing. However, this is unsuitable for IBS silicon carbide, since IBS silicon carbide layers usually have a layer thickness of 50-100 nm. Therefore, the amount of material removed by CMP described here is far too high.

WO03/071588 has disclosed a process for producing semiconductor wafers from silicon carbide, in which silicon carbide is deposited by means of CVD (chemical vapor deposition) on a substrate, is then separated from the substrate and the silicon carbide surface is smoothed either by mechanical polishing alone or by mechanical polishing followed by CMP polishing, with subsequent irradiation with GCIB (gas cluster ion beam). A slurry with a pH of 10-11, a temperature of 55° C., material removal rates of 0.1-0.2 μm/h and a polishing time of 12 hours is proposed for CMP. This results in silicon carbide surface roughnesses of 0.5 nm RMS. However, the amount of material removed by CMP, given the polishing parameters selected, amounts to 1.2-2.4 μm, which likewise means that this process cannot be used for thin IBS silicon carbide layers.

In all the known prior art which attempt to planarize the silicon carbide surface by means of CMP, mechanical polishing is provided prior to the CMP, but this is highly disadvantageous on account of the scratches which it produces and the associated large amount of material which has to be removed by CMP and/or the long polishing times. A further drawback of the processes described resides in increased process complexity on account of the polishing parameters selected.

A different approach is pursued in US 2005/0020084 A1. In this case, the silicon carbide layer is produced by what is known as the SmartCut process (layer transfer). The silicon carbide surface, which initially has a roughness of approximately 5 nm RMS, is smoothed by means of thermal oxidation at a temperature of 1000-1300° C. for 1 to 3 hours to a roughness of 1-2 nm RMS. This is followed by CMP polishing of the silicon carbide surface for 15 to 30 minutes. The thermal oxidation step is required in this process in order for the silicon carbide surface, which initially has an excessively high roughness caused by blistering at microcavities, to be planarized for the subsequent CMP polishing. This long oxidation step, however, makes this process relatively complex and uneconomical. Semiconductor layer structures produced by means of layer transfer are not considered further in the following text, since they do not form part of the present invention.

### SUMMARY OF THE INVENTION

It was an object of the invention to provide a semiconductor layer structure on which a high-quality epitaxial layer of semiconductor material, in particular of a nitride compound semiconductor, can be grown, and to provide an economical process for producing a semiconductor layer structure. These and other objects are achieved by a semiconductor layer structure which includes a monocrystalline silicon carbide layer on a silicon wafer, with a silicon wafer diameter of at least 150 mm, the silicon carbide layer having a surface roughness of at most 0.5 nm RMS and a micropipe density of at most 1 cm⁻² and also being free of defects which occur during crystal growth or during epitaxial deposition.

### BRIEF DESCRIPTION OF THE DRAWINGS

FIG. 1 illustrates one embodiment of a process and resulting layer structure of the subject invention.

FIG. 2 illustrates a further embodiment of a process and resulting layer structure of the subject invention.

### DETAILED DESCRIPTION OF THE PREFERRED EMBODIMENT(S)

In the context of the present invention, the term “silicon wafer” is intended to encompass all silicon-containing wafers which are suitable for the production of silicon carbide layers by implantation of carbon. The silicon wafer is preferably a wafer made from monocrystalline silicon, a wafer with an epitaxial silicon layer, a wafer with an SIMOX (separation by implantation of oxygen) substrate or an SOI (silicon on insulator) wafer.

The monocrystalline silicon carbide layer of the semiconductor layer structure according to the invention is preferably a layer produced by implantation of carbon into a silicon wafer.

The semiconductor layer structure according to the invention has a surface roughness of from 0.05-0.5 nm RMS. Therefore, the semiconductor layer structure according to the invention makes available a high-quality substrate for example for the deposition of nitride compound semiconductors, and therefore for applications in optoelectronics.

It is preferable for an epitaxial layer which includes a nitride compound semiconductor to be deposited on the silicon carbide layer of the semiconductor layer structure according to the invention. The epitaxial layer deposited preferably includes aluminum nitride (AlN), gallium nitride (GaN) or aluminum gallium nitride (AlGaN). The result, for the epitaxial layer containing a nitride compound semiconductor on a semiconductor layer structure according to the invention, is preferably a dislocation density of at most 10¹⁰ cm⁻², which represents an improvement over the prior art.

One particular advantage of the semiconductor layer structure according to the invention is that this structure is free of any defects which customarily occur during epitaxial deposition or crystal growth. In the case of crystal growth, such defects may include, for example, defects such as vacancies, interstitials and stacking faults, which have an adverse effect on the performance of the components produced thereon. In the case of epitaxial deposits, by way of example, misfit dislocations and stresses may form.

Furthermore, the semiconductor layer structure according to the invention has a micropipe density of at most 1 cm⁻². In the prior art, a micropipe density of 30-100 cm⁻² has been observed in silicon carbide wafers with a diameter of 100 mm, and even filling the micropipes by deposition of an epitaxial silicon carbide layer has only been able to reduce this level to 10 cm⁻².

The object is also achieved by a process for producing a semiconductor layer structure, in which carbon ions are implanted a certain depth into a silicon wafer, then the silicon wafer is heat-treated, with the result that a buried monocrystalline silicon carbide layer and, above and below the silicon carbide layer, noncrystalline transition regions are formed in the silicon wafer, then the upper silicon layer and the noncrystalline transition region located above the monocrystalline silicon carbide layer are removed, thereby uncovering the monocrystalline silicon carbide layer, and then the uncovered surface of the monocrystalline silicon carbide layer is subjected to chemical mechanical planarization down to a surface roughness of less than 0.5 nm RMS.

The term silicon wafer is intended to encompass all silicon-containing wafers which are suitable for the production of silicon carbide layers by implantation of carbon. The silicon wafer is preferably a wafer made from monocrystalline silicon, a wafer having an epitaxial silicon layer, a wafer having an SIMOX (separation by implantation of oxygen) substrate or an SOI (silicon on insulator) wafer.

One particular advantage of the process according to the invention is that, unlike in the prior art, there are no pretreatments carried out on the silicon carbide surface, such as preliminary mechanical polishing, heat treatment or thermal oxidation, prior to the chemical mechanical planarization. Therefore, the process according to the invention is particularly economical compared to the prior art.

The implantation of carbon ions into a silicon wafer, which preferably takes place at an angle of 0-20° with respect to a surface normal of the silicon wafer, and the subsequent heat treatment, which preferably takes place at a temperature of 1050-1400° C. for a period of 2-20 hours, lead to the formation of a buried monocrystalline silicon carbide layer and noncrystalline transition regions above and below this silicon carbide layer in the silicon wafer. It has been found that implantation at a shallow angle to the surface normal of the silicon wafer influences the roughness of the interface between the buried silicon carbide layer and the upper noncrystalline transition region. The implantation at a shallow angle has a certain smoothing effect. It is therefore particularly preferable for the carbon ions to be implanted at an angle of 1-10° with respect to a surface normal of the silicon wafer.

The upper silicon layer and the noncrystalline transition region located above the buried monocrystalline silicon carbide layer are then removed, preferably by means of a suitable chemical etching step. This uncovers the buried monocrystalline silicon carbide layer.

The latter is then subjected to chemical mechanical planarization (CMP), preferably using a slurry which contains colloidal silica, with a polishing time of preferably less than 30 min. A polishing time of less than 15 min is particularly preferred, and a polishing time of less than 5 min is most preferred. The CMP polishing is preferably carried out at a rotational speed of a polishing plate of 10-100 min⁻¹, and at a polishing pressure of 1-14 psi. The pH of the slurry used can be set by the addition of, for example, sodium hydroxide solution (NaOH) to the slurry and is preferably 8-11. The CMP polishing is preferably carried out at a polishing temperature of 20-60° C.

The CMP polishing in accordance with the invention smoothes the uncovered silicon carbide surface down to a roughness of less than 0.5 nm RMS. It is possible to achieve low roughnesses of as little as 0.05 nm RMS. Therefore, the process according to the invention allows the production of excellent substrates for epitaxial growth of semiconductor, in particular nitride compound semiconductors.

A second ion implantation, for example of helium ions, which preferably takes place at an angle of 0-20° with respect to a surface normal of the silicon wafer, is preferably carried out after the first ion implantation of carbon ions and the heat treatment of the silicon wafer. This produces a buried damage layer which comprises at least the interface between the silicon carbide layer and the upper noncrystalline transition region but not the whole of the silicon carbide layer. In this case too, the implantation at a shallow angle has a certain smoothing effect, which is boosted still further by the damage layer produced. Therefore, an angle of 1-10° with respect to a surface normal of the silicon wafer is particularly preferred for the second ion implantation. There is no provision for a heat treatment following the second ion implantation.

Next, the upper layers, i.e. the silicon layer, the noncrystalline transition region and the damage layer, are removed, preferably by etching. The uncovered silicon carbide surface is less rough compared to the process without a second ion implantation.

According to the invention, the silicon carbide surface is then planarized by means of CMP to a roughness of less than 0.5 nm RMS. On account of the less rough silicon carbide surface following the second ion implantation, this roughness is achieved with reduced CMP material removal levels and polishing times.

It is preferable for an epitaxial layer which contains a nitride compound semiconductor to be deposited on the silicon carbide surface, which in accordance with the invention has been subjected to chemical mechanical planarization down to a roughness of less than 0.5 nm RMS, of the semiconductor layer structure.

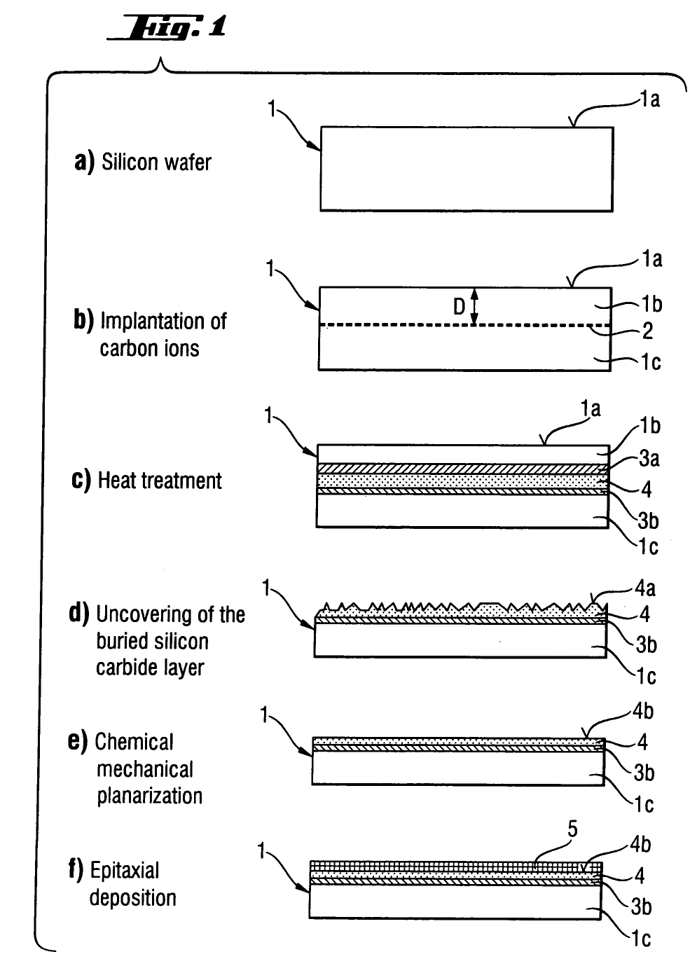

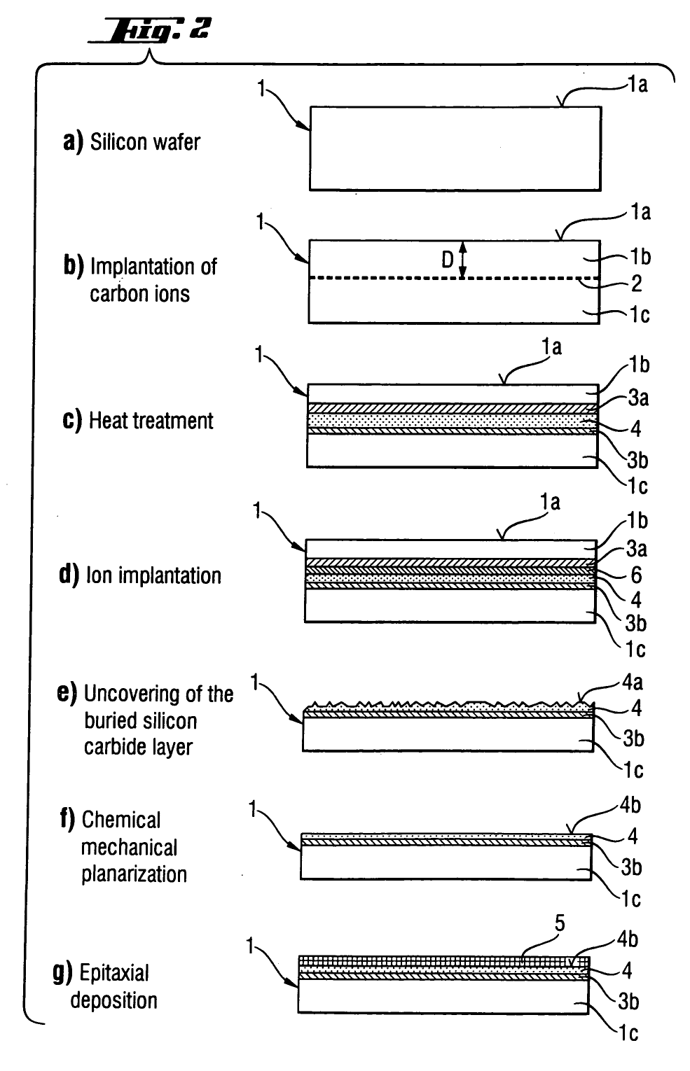

The text which follows explains the process according to the invention with reference to FIGS. 1 and 2.

FIG. 1 (a to f) shows how carbon ions 2 are implanted at a high velocity down to a predetermined depth D of a silicon wafer 1. It is possible that other layers may have been applied to the surface 1a of the silicon wafer before or after the implantation, or the wafer may have a surface which has already been structured. The silicon wafer is then heat-treated at a high temperature. The implanted carbon ions, together with the silicon atoms in the silicon wafer 1, form a monocrystalline silicon carbide layer 4. Noncrystalline transition regions 3a and 3b and silicon layers 1b and 1c are located above and below the monocrystalline silicon carbide layer.

The noncrystalline transition regions contain various polycrystalline silicon carbide precipitates, amorphous polycrystalline silicon carbide and silicon. The interface between the transition region 3a and an upper silicon layer 1b and an interface between the transition region 3a and the monocrystalline silicon carbide layer 4 are relatively rough. The upper silicon layer 1b and the noncrystalline transition region 3a are then removed in order to uncover the rough, buried silicon carbide surface 4a. This silicon carbide surface is then subjected to chemical mechanical planarization, resulting in a silicon carbide surface 4b which has been planarized down to a roughness of 0.05-0.5 nm RMS. Furthermore, an epitaxial layer 5 is deposited on the planarized silicon carbide surface 4b.

In FIG. 2 (a to g), the same process is carried out as in FIG. 1, except that a buried damage layer 6, which includes the interface between the silicon carbide layer 4 and the transition region 3a but does not completely include the buried silicon carbide layer 4, is produced with the aid of a second ion implantation, for example by implantation of helium ions. The upper silicon layer 1b, the noncrystalline transition region 3a and the damage layer 6 are then removed in order to uncover the buried silicon carbide surface 4a. The silicon carbide surface is then subjected to chemical mechanical planarization. The result is a silicon carbide surface 4b which has been planarized down to a roughness of 0.05-0.5 nm RMS. Then, an epitaxial layer 5 is deposited on the planarized silicon carbide surface 4b.

The removal of the upper silicon layer, the noncrystalline transition regions, and the defect zone, can be achieved by vapor phase etching of silicon. This is carried out either using hydrogen, hydrogen chloride, hydrofluoric acid or a mixture of the abovementioned substances at high temperature. It is also possible to add a gas which contains silicon and/or carbon during the etching operation.

In the case of low-energy implantation of approx. 10 keV, an undesirable, acicular growth of precipitates may form on the silicon carbide surface (Chen et al., Applied Physics Letters, Vol. 72, Issue 15, pp. 1926-1928). This acicular growth is preferably removed by means of a suitable chemical etching process. Following the removal of this acicular growth from the silicon carbide surface, according to the invention this surface is subjected to chemical mechanical planarization down to a roughness of 0.05-0.5 nm RMS and is then preferably cleaned.

The extremely low roughness levels of the silicon carbide surface achieved by the process according to the invention lead to the semiconductor layer structures produced being eminently suitable as substrates for epitaxial growth of nitride compound semiconductors.

Silicon carbide substrates are used in the production of optoelectronic components and of components for the heavy-current sector. The thin layer which is formed by the IBS silicon carbide can be increased in size by epitaxial growth using silane and propane as source gases and hydrogen as carrier gas.

Silicon carbide substrates are predominantly used as starting material for optoelectronic components, the silicon carbide surface being used as substrate for epitaxial growth. By way of example, epitaxial layers of GaN (gallium nitride), AlGaN (aluminum gallium nitride) and InAlGaN (indium aluminum gallium nitride) can be deposited on a silicon carbide surface, and in this way optoelectronic components and components for high-power and radio frequency electronics can be produced. Application examples include FETs (field effect transistors), blue LEDs (light emitting diodes) and photodiodes.

Having generally described this invention, a further understanding can be obtained by reference to certain specific examples which are provided herein for purposes of illustration only and are not intended to be limiting unless otherwise specified.

### EXAMPLES

### Example 1

Carbon ions at 180 keV, a dose of 6.6×10¹⁷ cm⁻², and at an angle of 7° to the surface normal of the semiconductor wafer were implanted into a wafer of monocrystalline silicon with a diameter of 150 mm maintained at 530° C. The semiconductor wafer was then heat-treated in an argon atmosphere at 1250° C. for 10 hours.

Following the heat treatment, helium ions were implanted into the silicon wafer at 80 keV, a dose of 8×10¹⁶ cm⁻² and at an angle of 7° to the surface normal of the silicon wafer.

The upper layers (silicon layer, transition region and damage layer) were then removed by etching using a 1:6 mixture of HF/HNO₃ over the course of 150 seconds.

The thickness of the silicon carbide layer uncovered was 75 nm. The surface roughness of the layer was then measured by means of AFM (atomic force microscopy). This revealed a value of 3.31 nm RMS on an area of 1×1 μm².

The uncovered silicon carbide surface was then subjected to chemical mechanical planarization with the aid of a Logitech CMP polishing machine. The following parameters were used for 3 minutes: an ESM-13 polishing disk, a slurry based on colloidal silica with a pH of 8 to 11, a pressure of 2 psi, a polishing plate rotational speed of 30 to 40 min⁻¹. The polishing took place at room temperature. 9 nm of silicon carbide was removed during the CMP polishing. The resulting surface roughness was then measured again by means of AFM. The result was a value of 0.36 nm RMS on an area of 1×1 μm².

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A semiconductor layer structure, including a monocrystalline silicon carbide layer on a silicon wafer, with a silicon wafer diameter of at least 150 mm, the silicon carbide layer having a surface roughness of at most 0.5 nm RMS and a micropipe density of at most 1 cm⁻² and being free of defects which occur during crystal growth or during epitaxial deposition.

2. The semiconductor layer structure of claim 1, wherein an epitaxial layer which includes a nitride compound semiconductor is deposited on the silicon carbide layer.

3. The semiconductor layer structure of claim 2, wherein the nitride compound semiconductor is aluminum nitride, gallium nitride or aluminum gallium nitride.

4. The semiconductor layer structure of claim 2, wherein the epitaxial layer has a dislocation density of less than 10¹⁰ cm⁻².

5. A process for producing a semiconductor layer structure of claim 1, comprising implanting carbon ions into a depth of a silicon wafer and heat treating the silicon wafer to form a buried monocrystalline silicon carbide layer, and above and below the silicon carbide layer, noncrystalline transition regions in the silicon wafer; removing an upper silicon layer and the noncrystalline transition region located above the monocrystalline silicon carbide layer, uncovering the monocrystalline silicon carbide layer; and chemical mechanical planarizing the uncovered surface of the monocrystalline silicon carbide layer to a surface roughness of less than 0.5 nm RMS.

6. The process of claim 5, wherein the implantation of the carbon ions takes place at an angle of 1-10° with respect to a surface normal of the silicon wafer.

7. The process of claim 5, wherein the heat treatment is carried out at a temperature of 1050-1400° C. for a period of 2-20 hours.

8. The process of claim 5, wherein the upper silicon layer and the upper noncrystalline transition region are removed by a chemical etching step.

9. The process of claim 5, wherein the chemical mechanical planarization is carried out using a slurry which contains colloidal silica.

10. The process of claim 9, wherein the slurry has a ph of 8-11.

11. The process of claim 5, wherein the planarizing time is less than 30 minutes.

12. The process of claim 11, wherein the planarizing time is less than 15 minutes.

13. The process of claim 11, wherein the planarizing time is less than 5 minutes.

14. The process of claim 5, wherein the chemical mechanical planarizing is carried out at a polishing pressure of 1-14 psi.

15. The process of claim 5, wherein the chemical mechanical planarizing is carried out at a polishing plate rotational speed of 10-100 min⁻¹.

16. The process of claim 5, wherein the chemical mechanical planarizing is carried out at a temperature of 20-60° C.

17. The process of claim 5, wherein the implantation of carbon ions and the subsequent heat treatment are followed by a second ion implantation at an angle of 0-20° with respect to a surface normal of the silicon wafer.

18. The process of claim 17, wherein the second ion implantation is an implantation of helium at an angle of 1-10° with respect to a surface normal of the silicon wafer.

19. The process of claim 5, wherein the chemical mechanical planarization of the silicon carbide surface is followed by the deposition of an epitaxial layer containing a nitride compound semiconductor on the semiconductor layer structure.
